(19) United States
(12) Patent Application Publication
(10) Pub. No.: US 2008/0017506 A1
(43) Pub. Date: Jan. 24, 2008

(54) Tubular Magnet Assembly

(76) Inventors: Anja Blondeel, Deinze (BE); Wilmert De Bosscher, Drongen (BE)

Correspondence Address: FOLEY AND LARDNER LLP;SUITE 500, 3000 K STREET NW, WASHINGTON, DC, 20007, US

(21) Appl. No.: 11/547,309

(22) PCT Filed: Mar. 17, 2005
(86) PCT No.: PCT/EP05/51226

§ 371 Date: Jul. 13, 2007

(30) Foreign Application Priority Data
Apr. 5, 2004 (EP) 04101404.4

(51) Int. Cl. H01F 7/00; C23C 14/35

(52) U.S. Cl. 204/298.18; 335/296

(57) ABSTRACT

A tubular magnet assembly mountable inside a cylindrical target to which the magnet assembly can relatively rotate or translate is disclosed. The magnet assembly discriminates itself from the state-of-the-art in that it comprises both a ‘near’ magnetic field for confinement of charge in the vicinity of the target in combination with a ‘far’ magnetic field reaching the substrate for guidance of charge towards the substrate. Such a magnet assembly also has the advantage that it is angularly directional and can be mounted centrally in an ion plating deposition unit.

### FIELD OF THE INVENTION

The invention relates to a tubular magnet assembly mountable inside a cylindrical target to which it can relatively rotate or translate and that is so designed that it yields an unbalanced magnetic field surrounding said cylindrical target.

### BACKGROUND OF THE INVENTION

Sputtering of a negatively charged target cylinder by impingement of low-pressure ionised noble gas atoms is well known in the art. The particles that are sputtered from the target surface arrive at a substrate where a thin layer of material builds up. Such sputtering can also be performed in a mixture of a noble and a reactive gas so that, in addition to the target particles that arrive, reaction products are formed at the surface of the substrate. The composition of the layer, i.e. the relative presence of target atoms and reaction product molecules, can be tuned as the deposition progresses by simply throttling the reactive gas valve. Deposition rates can be greatly increased by confining the ionising electrons in a closed loop magnetic tunnel—commonly called the ‘racetrack’—close to the target surface. Numerous static or dynamic magnet configurations mountable at the non-bombarded side of the target have been devised in order to confine the electrons in the most optimal way at the bombarded side of the target. ‘Optimal’ being dependent on the application, for example to ensure the most efficient target usage or to ensure a very uniform deposition. A non-exhaustive overview can be found in ‘Magnetron sputtering on large scale substrates: an overview on the state of the art’, by Reiner Kukla (‘Surface and Coating Technology’ 93 (1997) p. 1 to 6)

For the production of dense coatings of compound materials—e.g. to produce wear resistant ‘Diamond-Like-Coatings (DLC)’ or ‘Diamond-like-nanocomposites (DLN)’ or to produce optical high performance coatings—‘ion-plating’ is a known technique to influence the nucleation and growth of the coating during its formation. As ions of the noble gas or the reactive gas or the metal are omnipresent in the plasma, they are best suited to this end. However, in order to get a sufficient bombardment, the ionisation degree in the plasma must be large enough and part of the plasma must envelope the substrate. Different techniques such as ‘hot filament’, ‘hollow-cathode electron beam guns’ and ‘arc sources’ to name just a few are known in the art in order to increase the ionisation of the plasma. The substrate can become negatively charged by the impinging electrons (a ‘floating substrate’ that ‘self biases’) or by biasing the substrate negative with respect to the plasma.

The electrons confined in the racetrack by the magnet field of the magnetron can of course also be used to increase the ionisation of the plasma, but unfortunately this increased ionisation is only close to the target, and not in the vicinity of the substrate. However, ‘unbalanced’ magnet configurations have been devised where part of the magnetic flux lines extend to the substrate and part of the magnetic flux lines form a magnetic tunnel in the vicinity of the target (a basic reference on this subject being ‘Charged particle fluxes from planar magnetron sputtering sources’ from B. Window and N. Savvides, J. Vac. Sci. Technol. A 4 (2), March/April 1986). Electrons with a velocity component along the magnetic field line will gyrate around these extending field lines towards the substrate where they will ionise gas atoms. Electrons trapped in the magnetic tunnel will further take up their role to ionise the plasma in the vicinity of the target. Basically planar unbalanced magnetron arrangements fall apart in two different types:
Type I arrangements have a high flux density magnet surrounded by a low flux density magnet. This can conveniently be noted as ‘sNs’ or ‘nSn’ where the use of a capital letter refers to the high flux magnet and the lower case letter refers to the low flux magnet, the letter itself designating either a magnetic south pole (‘s’ or ‘S’) or a magnetic north pole (‘n’ or ‘N’). See FIG. 1 for an illustration.
Type II arrangements have a low flux density magnet surrounded by a high flux density magnet: ‘SnS’ or ‘NsN’. See FIG. 2 for an illustration.

Type II turns out to work best for planar arrangements. Plasma reactors employing ion plating have been described in EP 0 521 045 B1 of Teer Coatings ltd. This patent describes a reactor wherein the substrate is mounted in the middle of the reactor and is surrounded by a series of planar magnetrons of which at least one is unbalanced. However, the planar targets still suffer from their known inherent disadvantages such as a low target usage rate and—in the case of reactive sputtering—compound formation in the race track that is known in the art as ‘poisoning’. In addition a series of planar magnetrons is needed, each of them needing cooling facilities and power supplies thus making the installation more complex.

Cylindrical magnetrons are known to have a better target usage and are less prone to poisoning. As the target is round, it can be arranged to sputter atoms radially away from the target in angularly preferred directions as described in EP 0 045 822 A1. This application—considered to be the closest prior art—describes a cylindrical target wherein the electrons meander in racetracks arranged parallel to the cylinder axis connected to each other with arcuate end sections. Such an arrangement has the advantage that a single target can serve to coat different substrates that are rotating around the target in e.g. a carrousel. However, this design is balanced, i.e. the magnetic field lines all remain close to the surface of the target.

The inventors therefore sought for a magnet arrangement that combines a near magnetic field with a far extending magnetic field and can be used in a cylindrical target. With ‘far’ is meant: extending up to the substrate.

### SUMMARY OF THE INVENTION

The object of the invention is to provide a tubular magnet assembly that combines a near, electron confining magnetic field in combination with a far extending, electron guiding magnetic field arrangement. A further object of the invention is to describe how the spatial extent can conveniently be tuned. Another object of the invention is to optimise the magnetic field in terms of electron loss and target usage. A further object of the invention is to describe two possible main arrangements of such a far extending magnetic field tubular magnet assembly: one wherein the race tracks are substantially parallel to the axis of the tubular magnet assembly and one wherein the race tracks are substantially perpendicular to the axis of the tubular magnet assembly. The magnetron sputtering means is also described.

The requirement of having a radially extending, unbalanced magnetic field emanating from below a cylindrical surface poses some specific constraints on the design of the magnet assembly that prohibit the straightforward extrapolation from planar unbalanced magnet assemblies. The inventors found that an assembly as described by the combination of features in claim 1 fulfils the requirements. Specific features for preferred embodiments of the invention are set out in the dependent claims.

A tubular magnet assembly is provided in claim 1 that is mountable in a cylindrical target and relatively moveable thereto. It is most preferred that the magnet assembly remains stationary relative to the vacuum chamber and the target rotates around the assembly for the ease of construction. Also preferred is a rotating or a to-and-fro axial movement of the assembly whilst the target is stationary relative to the vacuum chamber since this can lead to the elimination of ghost plasma's that tend to appear in ion-plating magnetron arrangements. Of course also both the magnet assembly and the target can move relative to the vacuum chamber, as they move relative to one another but this mode is less preferred due to its complexity.

The magnet assembly comprises a series of magnet rows. Magnet rows are known in the art and are constructed from a series of permanent magnets fixed to a carrier tube. Within a row all magnets have an identical magnetic polarity orientation, the north-south vector being perpendicular to the cylinder surface. The tube is by preference a soft ferromagnetic material through which the magnetic field lines from different polarities connect. The permanent magnets are preferably from the rare earth magnets family of which the most notable members are SmCo (Samarium-Cobalt) and NdFeB (Neodynium-iron-boron) with different possible compositions. The former are preferred for their good temperature stability, the latter for their better price. Other compositions are of course note excluded from the invention.

The magnet rows extend longitudinally over substantially the whole length of said cylindrical target. With ‘longitudinally’ is meant parallel to the axis of the target tube. The magnet rows are inherently a little shorter than the target tube in order to allow for the bend in the racetrack. The magnet rows are arranged adjacent but separated from one another on the outer circumference of the tubular support. The magnet rows have an outer surface that is close to the inner side of the target tube. The magnetic field lines emanate—in case the outer surface has a ‘north’ (N) magnetic polarity—or the magnetic field lines arrive at this surface in case the outer surface has a ‘south’ (S) magnetic polarity. The magnetic field lines at the outer surface have a direction that is substantially perpendicular to the outer surface. The magnetic field lines at the inner side of the magnet rows—i.e. in the direction away from the target and towards the axis of symmetry—are substantially closed through the tubular support that easily guides the magnetic field lines.

Each of said magnet rows with index ‘i’ generates a magnetic flux at its outer surface ‘i’ that can be mathematically expressed as:

$${Φ}_{i} = {\int \int }_{outer surface i} {B}^{->} \cdot ⅆ {A}^{->}$$

where the \vec{B} is the magnetic induction vector and \vec{dA} is an elementary surface area. The scalar product only takes the component of the magnetic field that is perpendicular to the outer surface into account. As the outer surface of the magnet row is not a surface enclosing the complete magnet row, its value differs from zero. ‘Φᵢ’ is positive for an ‘N’ outer surface and negative for an ‘S’ outer surface. The flux of all magnet rows—‘K’ in number—added together is zero:
Σ_{i =1}^{K}Φᵢ≅0

As in practice the magnets composing the rows can differ slightly in flux value, the sum of the fluxes should be interpreted as being ‘close to zero’. More specifically ‘close to zero’ means having an absolute value smaller than 10%, or 5% or 2% of the sum of absolute fluxes
Σ_{i =1}^{K}|Φᵢ|.

The person skilled in the art will notice that this requirement states a clear distinction of the invention with the state-of-the-art unbalanced planar magnetron arrangement. In the latter a large difference in flux at the outer surface of the magnet assembly is essential, hence the sum of the fluxes at the outer surfaces will be different from zero implying that the flux lines will not all close on the outer surfaces but also on the soft magnetic support structure.

The fact that the sum of fluxes of the magnet arrangement according the invention is close to zero or zero does not necessarily imply that no field lines will close through the soft magnetic support structure or other parts of the sputtering chamber. Also the spatial arrangement and distances between rows will determine this. Anyhow the amount of flux lost to the support structure or to other parts of the sputtering chamber should be limited. Preferably it is less than 10%, or 5% or, most preferred less than 2% of the sum of the absolute fluxes.

The inventors realised that in order to obtain a magnetic field that is extending up to the substrate in order to allow the ion plating of the substrate the magnetic field has to be split up in:
a ‘near’ magnetic field that is close to the target in order to confine the electrons and excites the atoms, and
a ‘far’ magnetic field that extends towards the substrate and guides the electrons towards it.
   This can be realised by the features of the characterising portion of claim 1. A substantial part of the field lines emanating from (‘N’-case) or arriving at (‘S’-case) at least one magnet row (called ‘a reference row’) must connect to one or more magnet rows that is not adjacent to it. This part of the field lines will thus have to extend further away from the tubular magnet assembly before connecting to another row or rows of the magnet assembly and thus constitutes a ‘far’ magnetic field. The complementary part of the field lines that connect to the adjacent magnet rows will form a ‘near’ magnet field.

It will be immediately clear to the person skilled in the art that at least one of the magnet rows adjacent to a reference row must have a magnetic polarity that is opposite to the polarity of that reference row. Otherwise no magnet lines would connect to the adjacent rows and the near field could not form.

The relative strength of this ‘near’ and ‘far’ field is governed by the partition of field lines of a reference row between non-adjacent and adjacent rows. The stronger the flux of the reference row relative to the adjacent rows is, the larger the part of the field lines that connect to non-adjacent rows of that reference row will be. In the particular (non-claimed) case of 0% we arrive at the regular balanced magnetron array where a reference row only connects to its neighbouring rows. Dependent claim 2 claims a tubular magnet assembly where at least 20% of the magnetic field lines of a reference row connect to non-adjacent magnet rows. The 20% limit is the situation where the ‘far’ field—and hence the flux of the reference row—is the weakest. Dependent claim 3 describes the situation where the flux strength of a reference row has been increased to the extent that at least 33% of the field lines connect to a non-adjacent magnet row. For dependent claim 4 this has been increased to 50%.

The four different preferred ranges for the number of field lines that connect to non-adjacent magnet rows are:
from 0 to 20% (0 not included)
from 20% to 33%
from 33% to 50%
from 50% to 100% (but excluding 100%)
   The range to be selected is determined by the level of ion-plating one wants to achieve for a particular coating.

The number of reference rows is the subject of dependent claims 5 to 9. The case of one reference magnet row is claimed in claim 5. This reference row has a magnetic flux strength large enough to connect to another non-adjacent row or rows. This non-adjacent row or rows must have a polarity opposite to the polarity of the one reference magnet. The minimum number of magnet rows in a magnet assembly according the invention is thus four: one reference magnet row, two rows adjacent to the reference magnet row and one non-adjacent magnet row. The case can easily be extended towards two or three reference magnet rows. Subsequent claims 6 to 8 specifically claim embodiments with resp. 4, 5 and 6 reference rows. Claim 9 claims embodiments with 7 or more reference rows. Preferred is an even number of reference rows, more preferred is 4, 6, or 8 reference rows. The number of magnet rows that are not reference rows, i.e. those rows that only connect to their nearest neighbours, is immaterial although it will always be strictly larger than the number of reference rows.

The person skilled in the art will immediately realize that the magnet rows on themselves will not result in a workable magnetron. Indeed the racetrack is not closed and any electron generated would be lost immediately at the row ends. Therefore the row ends must be closed by means of suitable bends causing the electrons to meander along the surface of the target in one or more closed tracks. Many magnet configurations are known that lead to a suitable racetrack bend:
1. Rectangular bends as disclosed in EP 0 045 822 A1 (cited above)
2. Arcuate bends shaped in the form of a parabola, semi-ellipse, or a triangle as disclosed in WO 96/21750.
3. More complex bends as disclosed in WO 99/54911. As the erosion of target material is more pronounced at the bends (upon rotation the target material at the bends resides longer under the plasma) the magnet configurations of WO 96/21750 and WO 99/54911 are directed towards solving this groove formation problem that arises at the ends of the tubular target. Another way to solve the groove erosion problem has been disclosed in WO 98/35070. There the problem is solved by:
   Longitudinally offsetting the racetrack bends with respect to one another, or
   Modestly increasing the target material thickness at the ends of the target in the turn-around area of the bends.

It will be clear to the person skilled in the art that groove formation problem may equally well arise in the magnetron assembly according the invention. Therefore the solutions provided in WO 96/21750, WO 99//54911 and WO 98/35070 are equally well suited for the present invention and are therefore incorporated herein by reference.

The tubular magnet assembly as described above can be used in standard types of magnetron sputtering machines (as used for large area deposition e.g.), or it can be used in configurations where the target is arranged centrally or in any other possible configuration. Such machines are claimed in claim 10.

An alternative way to implement the invention, as claimed in claim 11, is to provide a tubular magnet assembly inside a cylindrical target and relatively moveable thereto, wherein the magnet rows of claim 1 have been replaced with magnet rings. These magnet rings are disposed parallel to one another on a tubular support that is shorter than the target tube. The centres of these rings are on the axis of the tubular support. Hence, the planes formed by the rings are not necessarily parallel to one another. The relative movement is preferably in longitudinal direction i.e. along the common axis of tubular magnet array and target, although a rotational movement and the combination of a rotary and translation movement is not excluded. The relative movement can be an oscillatory movement or a continuous movement. Again each of the magnet rings generates a certain magnetic flux at their outer surface. Again the sum of all these fluxes must be close to zero or zero. The tubular magnet assembly distinguishes itself from the prior art in that at least one of said magnet rings (called a ‘reference ring’) must have a substantial part of its field lines emanating from or arriving at its outer surface connect to a magnet ring different from the magnet rings directly adjacent to the reference ring. Again the magnet field is split up in a ‘near’ and a ‘far’ magnetic field. The far field extends towards the substrate and guides the electrons towards it.

Again changing the flux strength of the reference ring relative to the strength of its neighbouring ring, which is the subject of claims 12 to 14, can modulate the amount of field lines in the far field: the higher the flux strength of the reference ring, the more field lines will extend further away.

In claims 15 to 19 different tubular magnet assemblies containing one, two, three, four and five or more reference rings are claimed.

As for the tubular magnet assembly with magnet rows, the magnet assembly with rings can be used in any known sputtering apparatus where use is made of cylindrical targets into which the magnet assemblies can fit.

Finally, the ideas presented above can be readily extrapolated towards planar magnetrons. The planar unbalanced magnetrons that have been described in the ‘background of the invention’ all do not fall under the preamble of the main claims 1 and 11. This because the total flux at the outer surfaces of the magnets (be it rows or rings) does not add up to a near zero or zero number. Part of the magnetic field lines connect to the support structure which is not the case in the present invention.

Although the concept of magnetic field lines is fundamental to the theory of magnetism in particular and electromagnetism in general, the experimental visualization or quantification of it is not easy. The best way is to:
1. first determine the magnetic induction strength at the outer surface of the magnets as arranged in the assembly
2. introduce these experimentally found values into a magnetic field simulating programme together with the geometry of the magnet assembly.
3. generate a computer visualisation of the field lines up to the needed accuracy
4. count the number of field lines that connect from the reference magnet rows or rings to non-adjacent rows are rings in order to establish the partitioning of the lines.

Computation of the field line pattern can proceed through commercially available computer programmes such as:
1. ‘Opera-3D’, version 10 available from ‘Vector Fields’
2. ‘FEMM’, version 3.3, from David Meeker http://femm.foster-miller.net/index.html
3. ‘Amperes’, version 6.1, available from ‘Integrated Engineering’
4. ‘Ansys Emag’ version 8.0, available from ‘Ansys’
   Other experimental methods such as the use of iron filings dispersed on paper or the use of magnetic paper is also possible in order to establish the field line pattern.

Finally, it should be clear that the determination of the line pattern must be done in the final arrangement of the magnet assembly because the mutual interaction of magnets will density or dilute the field line densities at their surface.

### BRIEF DESCRIPTION OF THE DRAWINGS

The invention will now be described into more detail with reference to the accompanying drawings wherein

FIG. 1: shows a type I unbalanced magnetron

FIG. 2: depicts a type II unbalanced magnetron

FIG. 3: illustrates a first preferred embodiment of the invention according a cross section perpendicular to the axis of the supporting tube.

FIG. 4: represents a second preferred embodiment of the invention according a cross section perpendicular to the axis of the supporting tube.

FIG. 5: illustrates the magnet arrangement and the racetracks according the first preferred embodiment

FIG. 6: illustrates the magnet arrangement and the racetrack according the second preferred embodiment

FIG. 7: represents a third preferred embodiment of the invention

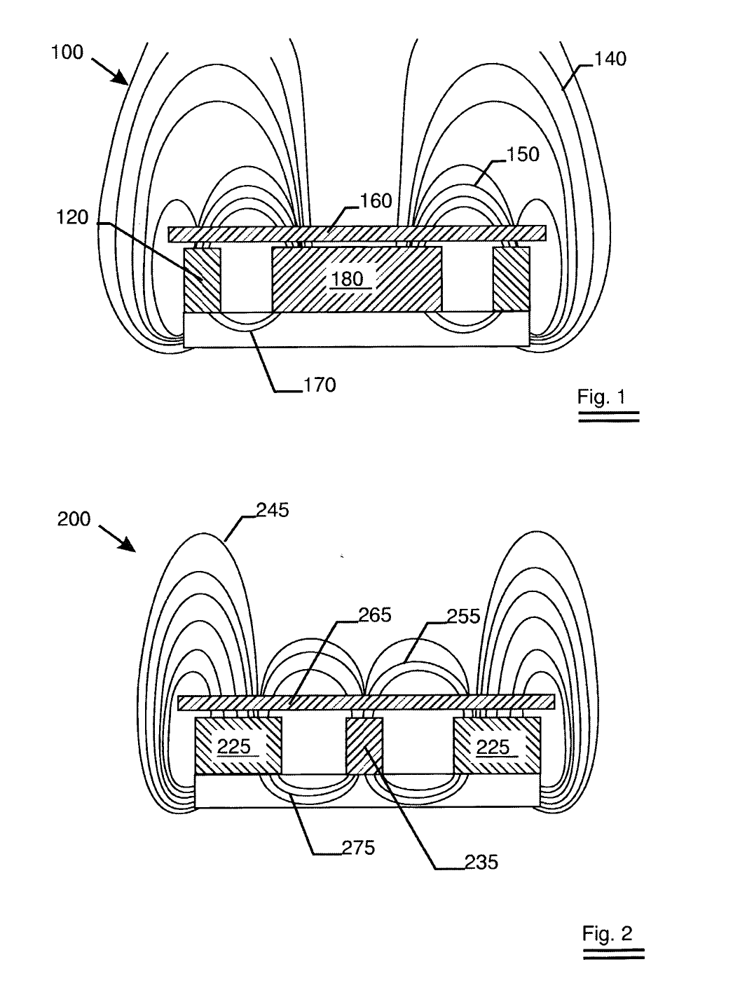

Note that the figures are for clarification of the invention only and should not be used for extraction of quantitative information, such as dimensions or number of field lines (even relative ratios), from them.

### DESCRIPTION OF THE PREFERRED EMBODIMENTS OF THE INVENTION.

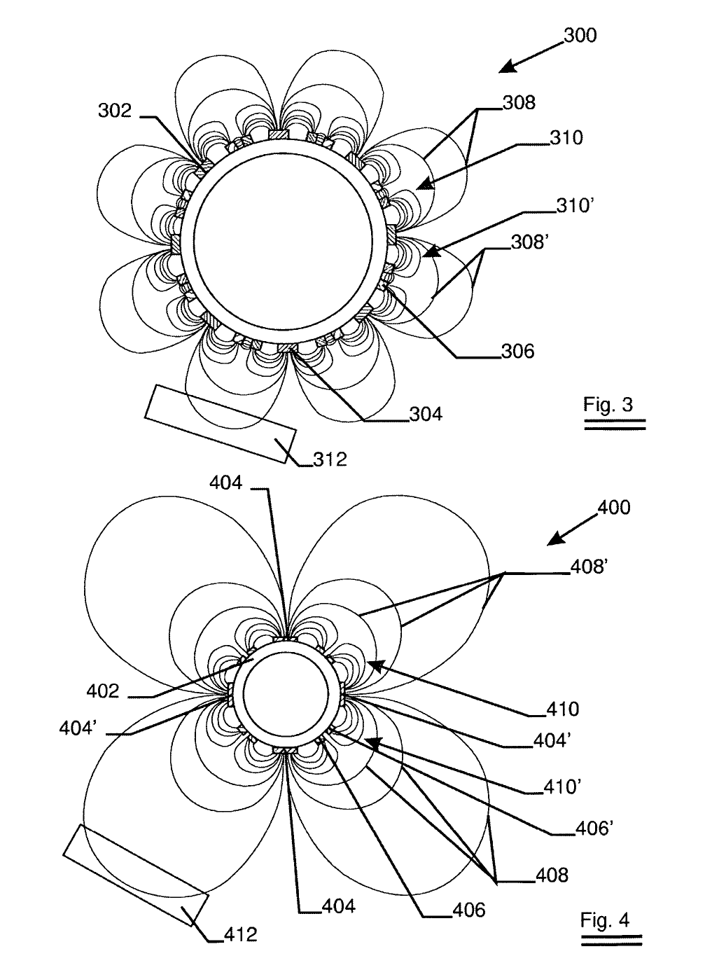

A first preferred embodiment is depicted in FIG. 3. A tubular magnet arrangement 300 as seen along the axis of symmetry is shown. On a soft magnetic carrier tube 302 made of pure iron—serving as a tubular support—different magnet rows 304 and 306 are mounted at the circumference of the tubular support 302. The magnet rows are substantially parallel to the symmetry axis of the tube and extend practically over the whole length of the cylindrical target. Magnetic field lines 308, 308′, 310 and 310′ emanate or arrive at the outer surfaces of the magnet rows. The polarity of the outer surface of the magnet rows is visualised by means of the hatching direction in the drawing: either ‘/’ (from upper right to lower left) or ‘\’ (from upper left to lower right) as seen from the centre. Each of the directions can be associated with just one of the magnetic polarities ‘N’ or ‘S’. The polarities of the outer surface alternate when subscribing a circle around the outside of the cylindrical target. The person skilled in the art will readily attribute a field line direction compatible with the ‘hatching to polarity’ association chosen. All depicted magnetic field lines arrive or emanate on one of the outer surfaces of the magnet rows. This means that the total magnetic flux of all magnet rows taken at the outer surface of the magnet rows adds to near zero or zero.

In this preferred embodiment, there are 8 reference magnetic rows 304 that are arranged equiangularly at the circumference of the tubular support. The orientation of the magnets is always perpendicular to the tubular support. The reference magnet rows are composed of individual NdFeB sintered magnets with a maximum energy product ((BH)ₘₐₓ) of 300 kJ/m³ (or about 38 MGOe). Such magnets are available from e.g. ‘Stanford Magnets Company’. The outer diameter of the support tube 302 is 170 mm and the width of the 304 magnet row is 28 mm and of the 306 row is 7 mm. All magnets are 10 mm thick. The means for fastening of the magnets is not essential to the invention: they can be glued, screwed, taped, mechanically fitted or held in place by whatever means, the means of self-attachment (magnets are attracted by the iron support) not being excluded.

The bunch of magnetic field lines emanating from (or arriving at) the outer surface of the reference row divides itself towards nearest neighbours (310 and 310′) and magnet rows further away (308 and 308′). The former form a ‘near’ magnetic field, the latter a ‘far magnetic field. The far magnetic field must extend up to the substrate 312.

A detailed analysis of the simulation of the magnetic field (with the simulation software FEMM, version 3.3) yields that 30% of the field lines emanating from a reference row arrive at a non-adjacent row. In this particular embodiment, the non-adjacent row is again a reference row (of course of the opposite polarity).

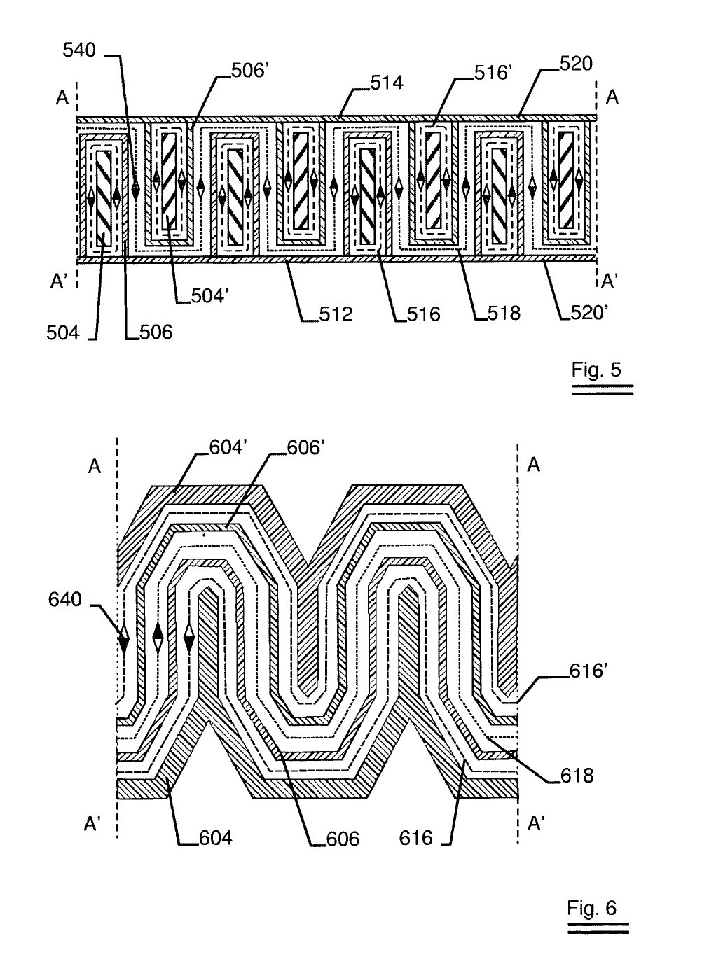

The end sections of this first embodiment have been slightly offset from one another (along the idea of WO 98/35070). This is depicted in, FIG. 5 wherein the tubular magnet assembly envelope has been rolled-out to describe the end sections and the racetracks that form. The reference rows 504, 504′ are surrounded by non-reference rows 506, 506′ that form loops around them. Adjacent reference rows are offset with respect to one another in the longitudinal direction of the magnet assembly. Two outer magnet rings 520, 520′ interconnect the non-reference rows of equal magnetic polarity. The magnet ring 520 has an opposite polarity to the 520′ magnet ring. When put into operation, around each reference row 504, 504′ a racetrack 516, 516′ develops in which electrons race in opposite directions as indicated by the double arrows 540. The direction followed by the electrons, depicted with a filled or empty arrow, will depend on the magnetic polarity of the rows. A weak, meandering (but closed) racetrack 518 develops between the non-reference rows. As this racetrack is confined by the far magnetic field, it will readily loose its electrons to the substrate.

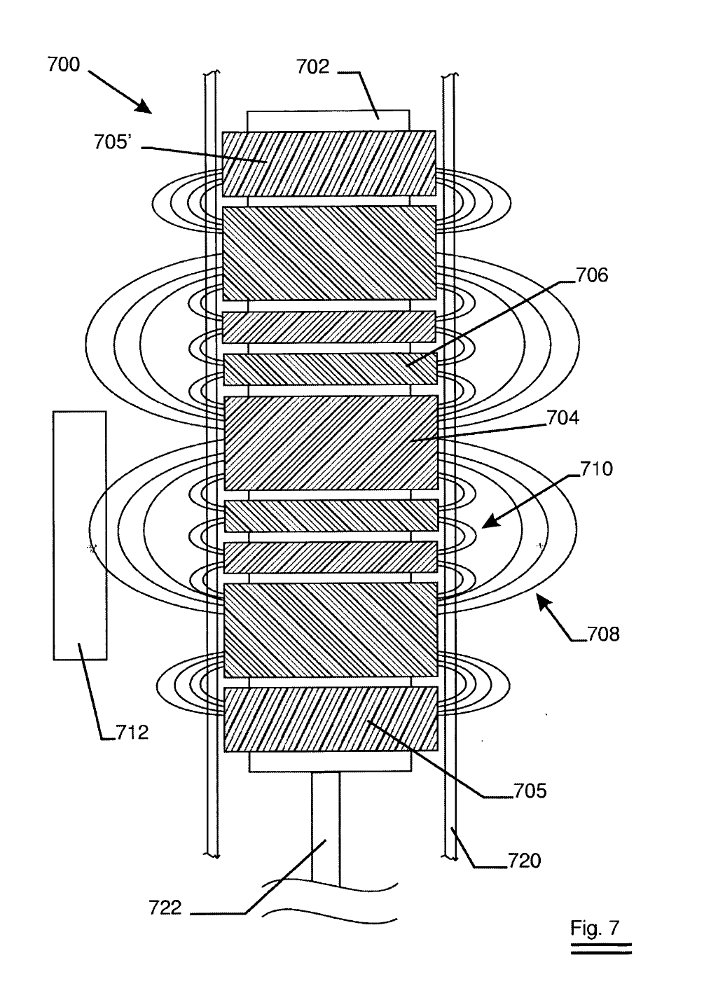

FIGS. 4 and 6 depict an alternative embodiment of the invention. In this case only four reference magnets 404 are equiangularly distributed. In between each pair of reference magnet rows 404, two non-reference magnet rows 406 are angularly evenly positioned. The same type of magnetic material has been used as in the first embodiment. Again a soft iron tubular support 402 of diameter 170 mm has been used. The width of the reference magnet row is 56 mm, and of the non-reference rows it is 7 mm. The number of field lines in the ‘far’ magnetic field is now 31% of the total field lines of the reference row.

The closing sections of the row are different from the ones of the first embodiment and have been depicted in FIG. 6 that is an unfolding of the tubular assembly. The problem of the erosion groove formation has been alleviated by making the bends in the shape of a triangle or a truncated triangle (in line with WO 96/21750). The reference rows 604, 604′ each form a closed assembly over the whole tubular support due to the introduction of the bends. However, four straight parts substantially parallel to axis of symmetry can be distinguished that correspond to the intersected rows 404, 404′ of FIG. 4. In between the eight non-reference rows 406, 406′ of the cross section in FIG. 4 now become two single loops 606, 606′ in between the reference rows 604, 604′. Upon operation, three racetracks will form: two rather pronounced racetracks 616, 616′ close to the target running in the same direction, and a less pronounced 618 that extends further away that runs in the direction opposite to the direction of 616 and 616′.

In a (not depicted) variant to this second embodiment, the number of reference rows was increased to 6 and the number of non-reference rows to 12. All other dimensions (diameter of tubular support, height and width of magnets, . . . ) and magnetic properties (strength and composition) were kept identical to that of the second embodiment. Only the angle between the reference rows was reduced from 90° to 60°. The non-reference rows were again angularly evenly distributed: two of them in between each pair of reference rows. The number of field lines connecting to non-adjacent magnet rows increased to 46%.

Although in the embodiments described, the number of non-reference rows is always equal to two times the number of reference rows, this is not a prerequisite of the invention. The magnetic field can be spread over a series of other non-adjacent rows all of equal polarity opposite to the reference row. Also the number of reference rows need not be even. As long as one row has at least a part of its field lines distributed over non-adjacent neighbours, the requirements of the invention are fulfilled.

A third preferred embodiment is depicted in FIG. 7. The magnet rows have been exchanged for magnet rings. The racetracks now become toroidal in form. The magnet assembly 700 can longitudinally move within the target tube 720. The magnet rings 704, 706, 705 are mounted on a soft iron support tube 702 that can be moved through a rod 722. There are 3 different magnet rings. There are the reference rings 704 and in between them the non-reference rings 706. The end-rings 705 are introduced to diminish the flaring of the magnetic lines towards the soft iron support tube. The magnetic polarities of subsequent rings alter between adjacent rings as is indicated by the hatching in the drawing. Two different magnetic fields form: the far magnetic field 708 is spanned between the reference rings 704 and rings non adjacent to it, the near magnetic field 710 is formed between adjacent rings. The far magnetic field extends up to the substrate 712.

1. A tubular magnet assembly mountable inside a cylindrical target and relatively moveable thereto, said tubular magnet assembly having a longitudinal axis of symmetry, said tubular magnet assembly comprising
a tubular support and a number of magnet rows disposed outwardly of said tubular support, said magnet rows being arranged substantially parallel to said symmetry axis over substantially the whole length of said cylindrical target, said magnet rows generating a substantially radially oriented magnetic field at their outer surface of either a north or a south magnetic polarity, each of said magnet rows generating a flux of magnetic field lines at their outer surface, the sum of all said fluxes of said magnetic rows being close to zero or zero, wherein
of at least one of said magnet rows a substantial part of the field lines emanating from or arriving at said at least one magnet row connect to one or more magnet row(s) different from the magnet rows directly adjacent to said at least one magnet row.

2. The tubular magnet assembly according to claim 1 wherein at least one fifth of the field lines emanating from or arriving at said at least one magnet row connect to one or more magnet row(s) different from the magnet rows directly adjacent to said at least one magnet row.

3. The tubular magnet assembly according to claim 1 wherein at least one third of the field lines emanating from or arriving at said at least one magnet row connect to one or more magnet row(s) different from the magnet rows directly adjacent to said at least one magnet row.

4. The tubular magnet assembly according to claim 1 wherein at least half of the field lines emanating from or arriving at said at least one magnet row connect to one or more magnet row(s) different from the magnet rows directly adjacent to said at least one magnet row.

5. The tubular magnet assembly according to claim 1 wherein one to three of said magnet rows have a substantial part of their field lines emanating from or arriving at said one to three magnet rows connect to one or more magnet row(s) different from the magnet rows directly adjacent to said one to three magnet rows.

6. The tubular magnet assembly according to claim 1 wherein four of said magnet rows have a substantial part of their field lines emanating from or arriving at said four magnet rows connect to one or more magnet row(s) different from the magnet rows directly adjacent to said four magnet rows.

7. The tubular magnet assembly according to claim 1 wherein five of said magnet rows have a substantial part of their field lines emanating from or arriving at said five magnet rows connect to one or more magnet row(s) different from the magnet rows directly adjacent to said five magnet rows.

8. The tubular magnet assembly according to claim 1 wherein six of said magnet rows have a substantial part of their field lines emanating from or arriving at said six magnet rows connect to one or more magnet row(s) different from the magnet rows directly adjacent to said six magnet rows.

9. The tubular magnet assembly according to claim 1, wherein seven or more of said magnet rows have a substantial part of their field lines emanating from or arriving at said seven or more magnet rows connect to one or more magnet row(s) different from the magnet rows directly adjacent to said seven or more magnet rows.

10. A magnetron sputtering means comprising a tubular magnet assembly according to claim 1 and a cylindrical target, said tubular magnet assembly being relatively rotatable inside said cylindrical target.

11. An tubular magnet assembly mountable inside a cylindrical target and relatively moveable thereto, said tubular magnet assembly having an axis, said tubular magnet assembly comprising, a tubular support and a number of magnet rings disposed parallel to one another, outwardly of said tubular support, each of said magnet rings having one centre point, said centre point coinciding with said axis of said tubular magnet assembly, said tubular magnet assembly extending over a part of said cylindrical target, said magnet rings having an outer surface generating an outwardly oriented magnetic field of either a north or a south polarity, each of said magnet rings generating a flux of magnetic field lines at their outer surface the sum of all said fluxes of said magnetic rings being close to zero or zero,
wherein
of at least one of said magnet rings a substantial part of its field lines emanating from its outer surface or arriving at its outer surface connect to one or more magnet ring(s) different from the magnet rings directly adjacent to said at least one magnet ring.

12. The tubular magnet assembly according to claim 11 wherein at least one fifth of the field lines emanating from or arriving at said at least one magnet ring connect to one or more magnet ring(s) different from the magnet rings directly adjacent to said at least one magnet ring.

13. The tubular magnet assembly according to claim 11 wherein at least one third of the field lines emanating from or arriving at said at least one magnet ring connect to one or more magnet ring(s) different from the magnet rings directly adjacent to said at least one magnet ring.

14. The tubular magnet assembly according to claim 11 wherein at least half of the field lines emanating from or arriving at said at least one magnet ring connect to one or more magnet ring(s) different from the magnet rings directly adjacent to said at least one magnet ring.

15. The tubular magnet assembly according to claim 11 wherein one of said magnet rings has a substantial part of the field lines emanating from or arriving at said one magnet ring connect to one or more magnet ring(s) different from the magnet rings directly adjacent to said one magnet ring.

16. The tubular magnet assembly according to claim 11 wherein two of said magnet rings have a substantial part of the field lines emanating from or arriving at said two magnet rings connect to one or more magnet ring(s) different from the magnet rings directly adjacent to said two magnet rings.

17. The tubular magnet assembly according to claim 11 wherein three of said magnet rings have a substantial part of the field lines emanating from or arriving at said three magnet rings connect to one or more magnet ring(s) different from the magnet rings directly adjacent to said five magnet rings.

18. The tubular magnet assembly according any one of to claim 11 wherein four of said magnet rings have a substantial part of the field lines emanating from or arriving at said four magnet rings connect to one or more magnet ring(s) different from the magnet rings directly adjacent to said four magnet rings.

19. The tubular magnet assembly according to claim 11, wherein five or more of said magnet rings have a substantial part of the field lines emanating from or arriving at said five or more magnet rings connect to one or more magnet ring(s) different from the magnet rings directly adjacent to said five or more magnet rings.

20. A magnetron sputtering means comprising a tubular magnet assembly according to claim 11 and a cylindrical target, said tubular magnet assembly being relatively moveable inside said cylindrical target.
